(19) United States
(12) Patent Application Publication
(10) Pub. No.: US 2024/0355527 A1
(43) Pub. Date: Oct. 24, 2024

(54) PACKAGE SUBSTRATE AND INDUCTOR COMPONENT

(71) Applicant: Murata Manufacturing Co., Ltd., Nagaokakyo-shi (JP)

(72) Inventors: Kenji NISHIYAMA, Nagaokakyo-shi (JP); Yoshimitsu USHIMI, Nagaokakyo-shi (JP); Koshi HIMEDA, Nagaokakyo-shi (JP); Nobuyoshi ADACHI, Nagaokakyo-shi (JP)

(21) Appl. No.: 18/761,630

(22) Filed: Jul. 2, 2024

Related U.S. Application Data
(63) Continuation of application No. PCT/JP2023/004746, filed on Feb. 13, 2023.

(30) Foreign Application Priority Data
Feb. 15, 2022 (JP) 2022-021422

(51) Int. Cl. H01F 27/255; H01F 17/00; H01F 17/04

(52) U.S. Cl. CPC H01F 27/255; H01F 17/0006; H01F 17/04; H01F 2017/0066; H01F 2017/048

(57) ABSTRACT

A package substrate that includes: an inductor layer having a magnetic body and inductor wires. The magnetic body includes a first magnetic layer and a second magnetic layer on at least one main surface of the first magnetic layer. The inductor wires are in the first magnetic layer and include a first wire and a second wire adjacent to each other and magnetically coupled. The second magnetic layer overlaps the first wire and the second wire in a thickness direction. The second magnetic layer has anisotropic magnetic permeability in which magnetic permeability in a main surface direction differs from the thickness direction. The magnetic permeability of the second magnetic layer in the main surface direction is higher than in the thickness direction. The magnetic permeability of the second magnetic layer in the main surface direction is higher than magnetic permeability of the first magnetic layer in a main surface direction.

### CROSS REFERENCE TO RELATED APPLICATIONS

The present application is a continuation of International application No. PCT/JP2023/004746, filed Feb. 13, 2023, which claims priority to Japanese Patent Application No. 2022-021422, filed Feb. 15, 2022, the entire contents of each of which are incorporated herein by reference.

### TECHNICAL FIELD

The present disclosure relates to a package substrate and an inductor component.

### BACKGROUND ART

Patent Document 1 discloses an inductor component including a first magnetic layer and a second magnetic layer containing a resin, a sintered substrate having a first main surface adhering to the first magnetic layer and a second main surface above which the second magnetic layer is disposed, and spiral wires disposed between the second magnetic layer and the substrate. In a fourth embodiment of Patent Document 1, multiple spiral wires 21C to 24C are arranged on the same plane, and the first spiral wire 21C is magnetically coupled to the second spiral wire 22C, and the third spiral wire 23C is magnetically coupled to the fourth spiral wire 24C. For example, when one of the first spiral wire 21C and the second spiral wire 22C has a first end serving as an input end and a second end serving as an output end, and the other spiral wire has a first end serving as an output end and a second end serving as an input end, the first spiral wire 21C and the second spiral wire 22C are negatively coupled.

Patent Document 2 discloses an inductor. The inductor includes a first wire and a second wire, a first magnetic layer, a second magnetic layer, and a third magnetic layer. The first wire and the second wire are adjacent to each other at a distance apart from each other. The first magnetic layer has a first surface continuous in a surface direction, a second surface spaced a distance apart from the first surface in a thickness direction and continuous in the surface direction, and an inner peripheral surface located between the first surface and the second surface to be in contact with an outer peripheral surface of the first wire and an outer peripheral surface of the second wire. The first magnetic layer contains resin and magnetic particles having a substantially spherical shape. The second magnetic layer has a third surface that is in contact with the first surface and a fourth surface spaced a distance apart from the third surface in a thickness direction. The second magnetic layer contains a resin and magnetic particles having an approximately flat shape. The third magnetic layer has a fifth surface that is in contact with the second surface, and a sixth surface spaced a distance apart from the fifth surface in the thickness direction. The third magnetic layer contains a resin and magnetic particles having an approximately flat shape. The second magnetic layer and the third magnetic layer each have relative permeability higher than relative permeability of the first magnetic layer. The third surface has a first recess recessed from a first facing portion facing the first wire in the thickness direction and a second facing portion facing the second wire in the thickness direction between the first facing portion and the second facing portion. The fourth surface has a second recess recessed from a third facing portion facing the first facing portion in the thickness direction and a fourth facing portion facing the second facing portion in the thickness direction between the third facing portion and the fourth facing portion. The fifth surface has a third recess recessed from a fifth facing portion facing the first wire in the thickness direction and a sixth facing portion facing the second wire in the thickness direction between the fifth facing portion and the sixth facing portion. The sixth surface has a fourth recess recessed from a seventh facing portion facing the fifth facing portion in the thickness direction and an eighth facing portion facing the second facing portion in the thickness direction between the seventh facing portion and the eighth facing portion. Patent Document 2 describes that while the substantially spherical magnetic particles in the first magnetic layer improve superimposed DC current characteristics, the substantially flat magnetic particles in the second magnetic layer and the third magnetic layer can achieve a high inductance and an excellent Q factor.
Patent Document 1: Japanese Unexamined Patent Application Publication No. 2020-13853
Patent Document 2: Japanese Unexamined Patent Application Publication No. 2021-28928

### SUMMARY OF THE DISCLOSURE

Patent Document 1 discloses a structure of a coupled inductor in which multiple wires arranged on the same plane are magnetically coupled. In contrast, Patent Document 2 discloses a laminate structure of magnetic bodies (magnetic layers) having magnetic particles with different shapes. Although describing respective effects of their structures, Patent Documents 1 and 2 do not describe the relationship between their structures and a coefficient of coupling. Thus, a desirable structure for a coupled inductor, more specifically, a structure with a high coefficient of coupling cannot be read from prior arts.

Particularly, from the result of the examination, the inventors have found that a structure entirely having a small thickness (hereafter also referred to as a low-profile structure) has difficulty in increasing a coefficient of coupling, and the prior arts fail to obtain an intended coefficient of coupling.

As described above, Patent Document 2 describes that a high inductance, and an excellent Q factor can be obtained with the use of the substantially flat magnetic particles and the substantially spherical magnetic particles, but has no description on the coefficient of coupling. Thus, an intended coefficient of coupling cannot be achieved by simply applying the structure described in Patent Document 2.

The present disclosure aims to provide a package substrate including an inductor layer having a low-profile structure and capable of increasing a coefficient of coupling. The present disclosure also aims to provide an inductor component having a low-profile structure and capable of increasing a coefficient of coupling.

A package substrate according to the present disclosure includes: an inductor layer including: a magnetic body including a first magnetic layer including first magnetic particles and a first resin and a second magnetic layer on at least one main surface of the first magnetic layer and including second magnetic particles and a second resin, and inductor wires in the first magnetic layer. The inductor wires include a first wire and a second wire adjacent to each other on a same plane along the at least one main surface of the first magnetic layer such that the first wire and the second wire are magnetically coupled. The second magnetic layer extends across the first wire and the second wire to overlap the first wire and the second wire in a thickness direction. The second magnetic layer has anisotropic magnetic permeability in which a magnetic permeability in a main surface direction differs from a magnetic permeability in the thickness direction. The magnetic permeability of the second magnetic layer in the main surface direction is higher than the magnetic permeability of the second magnetic layer in the thickness direction. The magnetic permeability of the second magnetic layer in the main surface direction is higher than magnetic permeability of the first magnetic layer in a main surface direction.

An inductor component according to the present disclosure includes: a magnetic body including a first magnetic layer including first magnetic particles and a first resin and a second magnetic layer on at least one main surface of the first magnetic layer and including second magnetic particles and a second resin, inductor wires in the first magnetic layer; and an outer electrode on an outer surface of the magnetic body and electrically connected to the inductor wires. The inductor wires include a first wire and a second wire adjacent to each other on a same plane along the at least one main surface of the first magnetic layer so that the first wire and the second wire are magnetically coupled. The second magnetic layer extends across the first wire and the second wire so as to overlap the first wire and the second wire in a thickness direction. The second magnetic layer has anisotropic magnetic permeability in which a magnetic permeability in a main surface direction differs from a magnetic permeability in the thickness direction. The magnetic permeability of the second magnetic layer in the main surface direction is higher than the magnetic permeability of the second magnetic layer in the thickness direction. The magnetic permeability of the second magnetic layer in the main surface direction is higher than the magnetic permeability of the first magnetic layer in the main surface direction.

The present disclosure can provide a package substrate including an inductor layer with which even a low-profile structure can increase the coefficient of coupling. The present disclosure can also provide an inductor component including an inductor layer with which even a low-profile structure can increase the coefficient of coupling.

### BRIEF DESCRIPTION OF THE DRAWINGS

FIG. 1 is a schematic perspective view of an example of the basic structure of an inductor layer constituting a package substrate according to the present disclosure.

FIG. 2 is a schematic cross-sectional view of an example of a package substrate according to the present disclosure.

FIG. 3 is a schematic cross-sectional view of an example of a semiconductor composite device including a voltage regulator and a load mounted on the package substrate illustrated in FIG. 2.

FIG. 4 is a schematic block diagram of an example of a circuit configuration of a semiconductor composite device.

FIG. 5 is a schematic cross-sectional view of an example of a laminate structure of an inductor layer.

FIG. 6 is a schematic cross-sectional photo of another example of a laminate structure of an inductor layer.

FIG. 7 is a schematic diagram of an example of a magnetic flux at a coupled inductor disposed in a magnetic body having a laminate structure including a first magnetic layer and a second magnetic layer.

FIG. 8 is a schematic diagram of an example of a magnetic flux at a coupled inductor disposed in a magnetic body having a single-layer structure simply including a first magnetic layer.

FIG. 9 is a schematic cross-sectional view of a particle flattening ratio.

FIG. 10 is a schematic cross-sectional view of another example of a laminate structure of an inductor layer.

FIG. 11 is a graph of magnetic permeability dependence of a single-layer structure including a magnetic body entirely formed from the same isotropic material.

FIG. 12 is a graph of inductance dependence and a coefficient of coupling with respect to an anisotropy ratio of a second magnetic layer.

FIG. 13 is a graph obtained by converting the graph illustrated in FIG. 12 into magnetic permeability dependence of the second magnetic layer in a main surface direction.

FIG. 14 is a graph of magnetic permeability dependence of a first magnetic layer in a laminate structure illustrated in FIG. 5.

FIG. 15 is a graph of magnetic permeability dependence of an SW noise reduction effect when the anisotropy ratio of the second magnetic layer is 10.

FIG. 16 is a graph of magnetic permeability dependence of an SW noise reduction effect when the anisotropy ratio of the second magnetic layer is 7.

FIG. 17 is a graph of magnetic permeability dependence of an SW noise reduction effect when the anisotropy ratio of the second magnetic layer is 4.

FIG. 18 is a graph of dependence with respect to an inter-wire distance in the laminate structure illustrated in FIG. 5.

FIG. 19 is a schematic cross-sectional view of an example of a semiconductor composite device mounted on a motherboard.

FIG. 20 is a schematic cross-sectional view of another example of a semiconductor composite device mounted on a motherboard.

### DESCRIPTION OF THE PREFERRED EMBODIMENTS

A package substrate and an inductor component according to the present disclosure are described below.

However, the present disclosure is not limited to the following structure, and may be changed as appropriate within a range not changing the gist of the present disclosure to be applicable. A combination of two or more of preferable structures of the present disclosure described later is also included in the present disclosure.

The drawings described later are schematic diagrams, and may differ from actual products in, for example, their dimensions or aspect ratios.

A package substrate according to the present disclosure includes an inductor layer. The inductor layer includes a magnetic body including a first magnetic layer and a second magnetic layer, and inductor wires disposed in the first magnetic layer and functioning as an inductor. The package substrate according to the present disclosure may further include a capacitor layer including a capacitor inside, in addition to the inductor layer.

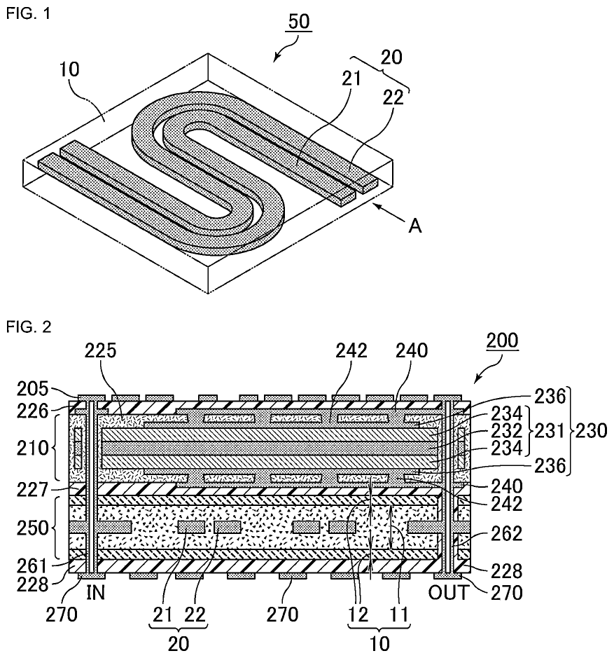

FIG. 1 is a schematic perspective view of an example of the basic structure of an inductor layer constituting the package substrate according to the present disclosure.

An inductor layer 50 illustrated in FIG. 1 includes a magnetic body 10 and inductor wires 20 functioning as an inductor. The structure of the magnetic body 10 is described in detail later. The inductor wires 20 include a first wire 21 and a second wire 22 disposed adjacent to each other on the same plane. The first wire 21 and the second wire 22 are magnetically coupled to each other. More specifically, the inductor wires 20 function as a coupled inductor.

The inductor component according to the present disclosure includes a magnetic body including a first magnetic layer and a second magnetic layer, inductor wires disposed in the first magnetic layer and functioning as an inductor, and an outer electrode disposed on an outer surface of the magnetic body and electrically connected to the inductor wires.

The inductor component according to the present disclosure is a chip component including a magnetic body and inductor wires similar to the inductor layer constituting the package substrate according to the present disclosure. For example, when an outer electrode electrically connected to end portions of the first wire 21 and the second wire 22 illustrated in FIG. 1 is disposed on an outer surface of the magnetic body 10, the inductor component according to the present disclosure can be obtained.

In the package substrate and the inductor component according to the present disclosure, the inductor wires may include three or more wires magnetically coupled to each other. In this case, the wire or wires other than the first wire and the second wire may be disposed on a plane the same as or different from a plane on which the first wire and the second wire are disposed. The inductor wires may be positively or negatively coupled.

In the present disclosure, the thickness of the entire package substrate is preferably smaller than or equal to 2.0 mm, or more preferably smaller than or equal to 1.6 mm in consideration of, for example, thickness reduction of a system or heat dissipation characteristics of a logical operation circuit. The thickness of the entire package substrate is, for example, greater than or equal to 0.5 mm.

The thickness of the inductor layer in the package substrate according to the present disclosure is preferably smaller than or equal to 0.6 mm, or more preferably smaller than or equal to 0.3 mm to meet the requirement for thickness reduction of the package substrate. When multiple inductor layers are disposed on the package substrate, the total thickness of the inductor layers is preferably within the above range. The thickness of the inductor layer is, for example, greater than or equal to 0.25 mm. Similarly, the thickness of the magnetic body in the inductor component according to the present disclosure is preferably within the above range.

When the package substrate according to the present disclosure includes a capacitor layer, the thickness of the capacitor layer is preferably smaller than or equal to 1.2 mm, or more preferably smaller than or equal to 0.8 mm to meet the requirement for thickness reduction of the package substrate. When the package substrate includes multiple capacitor layers, the total thickness of the capacitor layers is preferably within the above range. The thickness of the capacitor layer is, for example, greater than or equal to 0.25 mm.

### [Package Substrate]

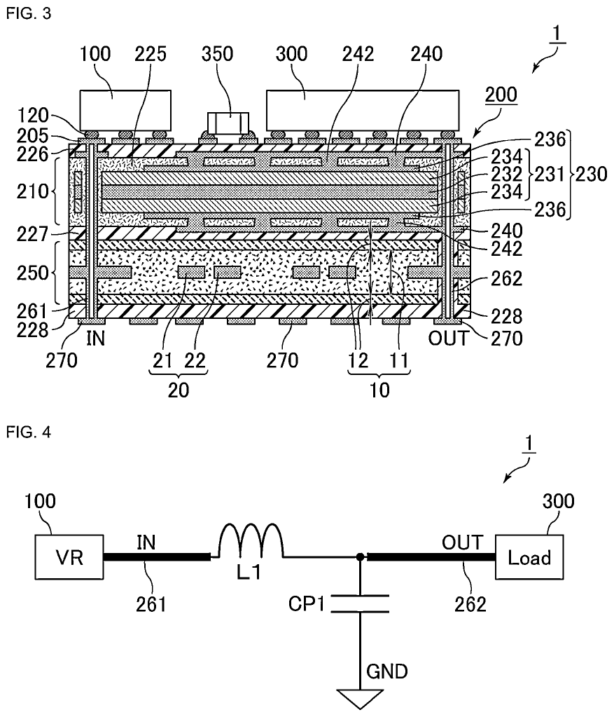

FIG. 2 is a schematic cross-sectional view of an example of a package substrate according to the present disclosure. FIG. 3 is a schematic cross-sectional view of an example of a semiconductor composite device including a voltage regulator and a load mounted on the package substrate illustrated in FIG. 2. FIG. 4 is a schematic block diagram of an example of a circuit configuration of a semiconductor composite device.

A package substrate 200 illustrated in FIG. 2 includes a capacitor layer 210 including a capacitor, and an inductor layer 250 including an inductor. The package substrate 200 may simply include the inductor layer 250 without the capacitor layer 210. The inductor layer 250 has the same structure as the inductor layer 50.

The capacitor layer 210 constitutes a capacitor CP1 (refer to FIG. 4), and the inductor layer 250 constitutes an inductor L1 (refer to FIG. 4).

A resin layer 226 serves as an insulator layer to insulate the exposed surface of the capacitor layer 210. A resin layer 227 is disposed between the capacitor layer 210 and the inductor layer 250. A resin layer 228 serves as an insulator layer to insulate the exposed surface of the inductor layer 250.

In a semiconductor composite device 1 illustrated in FIG. 3, a voltage regulator (VR) 100 and a load 300 are mounted on the package substrate 200. The load 300 is, for example, a semiconductor integrated circuit (IC) such as a logical operation circuit or a storage circuit. On a mount surface of the package substrate 200, an electronic device 350 other than the voltage regulator 100 and the load 300 may be mounted.

The voltage regulator 100 includes an active element (not illustrated) such as a semiconductor switching element, and adjusts a DC voltage supplied from an external device to a voltage level appropriate to the load 300 by controlling the duty of the active element.

The package substrate 200 has the voltage regulator 100 and the load 300 mounted on its surface to form the semiconductor composite device 1 as one package component.

A chip component may be mounted on the package substrate 200 as the electronic device 350, such as a decoupling capacitor or a choke inductor as a countermeasure against noise, a diode element for surge protection, or a resistance element as a voltage divider. From the output of the voltage regulator 100 to the input of the load 300, the inductor L1 and a capacitor CP1 (refer to FIG. 4) are disposed as ripple filters to form, for example, a chopper step-down switching regulator.

The package substrate 200 includes, on its upper surface on which the load 300 is mounted, lands on which electronic components including the load 300 and the voltage regulator 100 are mounted, and an upper-surface terminal layer 205 that electrically connects the lands. The package substrate 200 further includes, on its bottom surface opposite to the upper surface of the package substrate 200, a bottom-surface terminal layer 270 that allows the semiconductor composite device 1 to be mounted on a motherboard (not illustrated). A wire used to form a circuit may further be formed in the bottom-surface terminal layer 270.

In the semiconductor composite device 1 illustrated in FIG. 3, the inductor L1 in the inductor layer 250 is connected between an input terminal IN and an output terminal OUT of the package substrate 200. The inductor L1 is connected to the voltage regulator 100 at the input terminal IN, and connected to the load 300 at the output terminal OUT. The capacitor CP1 in the capacitor layer 210 is connected between the output terminal OUT and a ground terminal GND (refer to FIG. 4).

The voltage regulator 100 and the inductor L1 and the capacitor CP1 in the package substrate 200 form a chopper step-down switching regulator. The inductor L1 and the capacitor CP1 function as ripple filters of the step-down switching regulator.

The switching regulator lowers the DC voltage of, for example, 5 V input from an external device to 1 V to be supplied to the load 300.

The package substrate 200 preferably includes through-hole conductors 261 and 262 obtained by metalizing through-holes extending through the package substrate 200 in the thickness direction. The package substrate 200 having the through-hole conductors 261 and 262 allows the components to be electrically connected to one another in the thickness direction of the package substrate 200. Thus, when the through-hole conductors 261 and 262 that allow a power supply wire from the voltage regulator 100 to the load 300 through ripple filters (the capacitor layer 210 and the inductor layer 250) to be routed in a direction perpendicular to the circuit plane is used without using a flat wire formed in the upper-surface terminal layer 205, the wire impedance can be lowered and the layout of the circuit plane can be minimized. Thus, the size of the semiconductor composite device 1 can be reduced.

For ease of understanding the above description, FIG. 4 illustrates, by taking a chopper step-down switching regulator as an example, the relationship between a circuit from the voltage regulator 100 to the load 300 and the configuration of the through-hole conductor. As illustrated in FIG. 4, the power supply wire from the output of the voltage regulator 100 to the input of the load 300 is connected through the inductor L1 at the shortest distance and over the smallest area. This configuration is particularly effective for the semiconductor composite device 1 having a thin substrate structure such as the package substrate 200.

The inductor layer 250 constituting the package substrate 200 is described now in detail.

The inductor layer 250 is formed by adding an inductance component to a part of a substrate inner wire, serving as one component of the package substrate 200.

The inductor layer 250 includes a coupled inductor. The coupled inductor used for the package substrate 200 constituting the semiconductor composite device 1 is to have high inductance and a high coefficient of coupling. The inductor wires are negatively coupled.

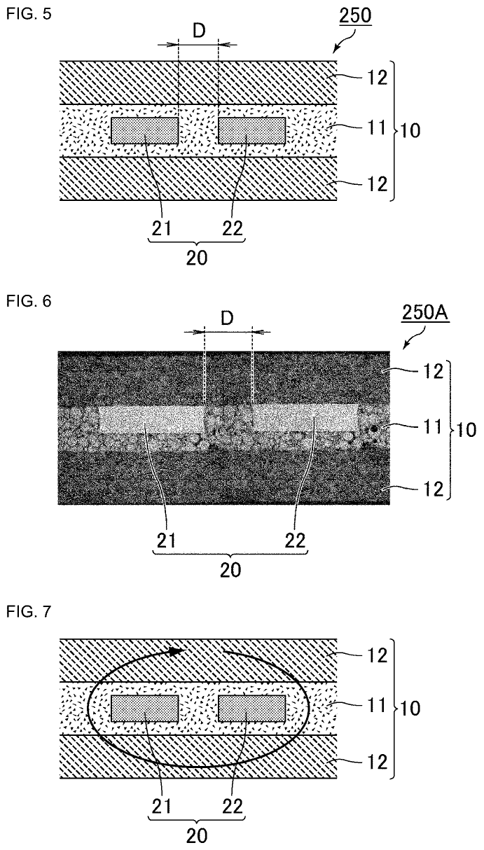

FIG. 5 is a schematic cross-sectional view of an example of a laminate structure of an inductor layer. FIG. 5 illustrates a cross section observed in direction A in FIG. 1.

As in the inductor layer 50 illustrated in FIG. 1, the inductor layer 250 illustrated in FIG. 5 includes the magnetic body 10 and the inductor wires 20 functioning as an inductor.

The magnetic body 10 includes a first magnetic layer 11 and second magnetic layers 12. In the example illustrated in FIG. 5, the second magnetic layers 12 are disposed on both main surfaces of the first magnetic layer 11. More specifically, the first magnetic layer 11 is held between the second magnetic layers 12 on both sides in the thickness direction.

The inductor wires 20 are disposed in the first magnetic layer 11. The inductor wires 20 include the first wire 21 and the second wire 22 disposed adjacent to each other on the same plane extending along the main surfaces of the first magnetic layer 11. The first wire 21 and the second wire 22 are magnetically coupled to each other. More specifically, the inductor wires 20 function as a coupled inductor.

The inductor wires 20 may include three or more wires magnetically coupled to one another. When the inductor wires 20 are included in the package substrate 200 constituting the semiconductor composite device 1, the inductor layer 250 constituting the package substrate 200 is also required to have a very thin structure (low-profile structure). Thus, the inductor wires 20 preferably have a single layer, but may have multiple layers.

As described later, the distance between the first wire 21 and the second wire 22 adjacent to each other on the same plane (the length denoted with D in FIG. 5, or also referred to as an inter-wire distance) is desirably smaller to increase the coefficient of coupling. However, a relatively large distance is required for insulation voltage resistance between inductors or for a process of forming a magnetic layer between wires. In addition, with a requirement of decreasing wire resistance to flow a large current, the first wire 21 and the second wire 22 are required to have a greater thickness. The material of the first wire 21 and the second wire 22 is, for example, copper (Cu).

A metal wire formed by patterning a copper core member (copper foil) formed by, for example, electroforming or rolling to have a thickness of approximately 100 μm into a coil shape with, for example, a photoresist, and then performing etching on the patterned member is usable as the inductor wires 20 such as the first wire 21 and the second wire 22.

FIG. 6 is a schematic cross-sectional photo of another example of a laminate structure of an inductor layer.

In the inductor layer 250 illustrated in FIG. 5, the first magnetic layer 11 is located between the second magnetic layers 12 and the first wire 21. Instead, as in an inductor layer 250A illustrated in FIG. 6, no first magnetic layer 11 may be located between the second magnetic layer 12 and the first wire 21. More specifically, the upper surface or the bottom surface of the first wire 21 may be located at the interface between the first magnetic layer 11 and each second magnetic layer 12. The same applies to the second wire 22.

The interface between the first magnetic layer 11 and each second magnetic layer 12 may be uneven as in the case of Patent Document 2, but is preferably flat as illustrated in FIG. 6.

Specific structure parameters of the inductor layer 250A illustrated in FIG. 6 are as follows:
thickness of magnetic body 10: 0.6 mm
thickness of first magnetic layer 11: 120 μm
thickness of second magnetic layers 12: 240 μm
thickness of first wire 21: 100 μm, thickness of second wire 22: 100 μm
width of first wire 21: 400 μm, width of second wire 22: 400 μm
inter-wire distance D: 200 μm

The first magnetic layer 11 includes first magnetic particles and a first resin.

The first magnetic layer 11 preferably has isotropic magnetic permeability in which magnetic permeability in the main surface direction is equivalent to magnetic permeability in the thickness direction. For example, when the first magnetic particles are spherical, the first magnetic layer 11 has isotropic magnetic permeability.

The second magnetic layers 12 each include second magnetic particles and a second resin.

The second magnetic layers 12 are disposed across the first wire 21 and the second wire 22 to overlap the first wire 21 and the second wire 22 in the thickness direction. As described above, the first magnetic layer 11 or no first magnetic layer 11 may be located between the second magnetic layer 12 and the first wire 21 and between the second magnetic layer 12 and the second wire 22. More specifically, each second magnetic layer 12 may be in contact with or in no contact with the first wire 21 and the second wire 22. When the inductor wires 20 include three or more wires, the second magnetic layers 12 are disposed across these wires to overlap, in the thickness direction, the wires magnetically coupled to one another.

The second magnetic layer 12 has anisotropic magnetic permeability in which magnetic permeability in the main surface direction differs from magnetic permeability in the thickness direction. For example, when second magnetic particles are flat, the second magnetic layer 12 has anisotropic magnetic permeability.

More specifically, the magnetic permeability of the second magnetic layer 12 in the main surface direction is higher than the magnetic permeability of the second magnetic layer 12 in the thickness direction.

In addition, the magnetic permeability of the second magnetic layer 12 in the main surface direction is higher than the magnetic permeability of the first magnetic layer 11 in the main surface direction.

The magnetic permeability in the main surface direction and the magnetic permeability in the thickness direction of each of the first magnetic layer 11 and the second magnetic layer 12 can be measured by, for example, a network analyzer.

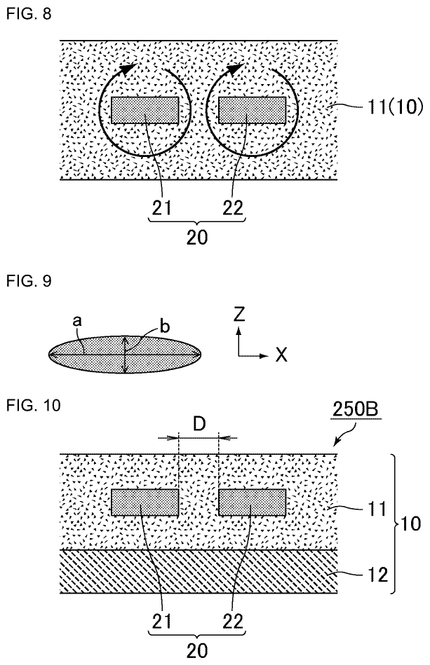

FIG. 7 is a schematic diagram of an example of a magnetic flux at a coupled inductor disposed in a magnetic body having a laminate structure including a first magnetic layer and a second magnetic layer. FIG. 8 is a schematic diagram of an example of a magnetic flux at a coupled inductor disposed in a magnetic body having a single-layer structure simply including a first magnetic layer.

To increase the coefficient of coupling of the first wire 21 and the second wire 22 magnetically coupled to each other, as illustrated in FIG. 7, desirably, a magnetic flux surrounds the periphery of the first wire 21 and the second wire 22 adjacent to each other. In the laminate structure of the first magnetic layer 11 and the second magnetic layers 12, the second magnetic layers 12 are each disposed across the first wire 21 and the second wire 22, the magnetic permeability of the second magnetic layer 12 in the main surface direction is higher than the magnetic permeability of the second magnetic layer 12 in the thickness direction, and the magnetic permeability of the second magnetic layer 12 in the main surface direction is higher than the magnetic permeability of the first magnetic layer 11 in the main surface direction. Thus, as shown in FIG. 7, a magnetic flux may surround the periphery of the first wire 21 and the second wire 22 adjacent to each other. Thus, even a low-profile structure can increase the coefficient of coupling. In contrast, as illustrated in FIG. 8, in a single-layer structure simply including the first magnetic layer 11, a magnetic flux is more likely to surround the periphery of each of the first wire 21 and the second wire 22.

A material with high magnetic permeability generally has poor flowability. Thus, filling the inductor wires 20 having a large wire thickness and a small inter-wire distance with a material having high magnetic permeability is not successfully performed. As illustrated in FIG. 7, preferably, the first magnetic layer 11 is formed by filling the inductor wires 20 with a material having high flowability and low magnetic permeability, and laminating, on the first magnetic layer 11, the second magnetic layers 12 containing a material with high magnetic permeability and having higher magnetic permeability in the main surface direction than magnetic permeability in the thickness direction.

Preferably, a ratio of the magnetic permeability of the second magnetic layers 12 in the main surface direction to the magnetic permeability of the second magnetic layers 12 in the thickness direction (hereafter also referred to as an anisotropy ratio) is greater than or equal to 4. In that case, the magnetic permeability of the first magnetic layer 11 in the main surface direction is preferably greater than or equal to 10 and smaller than or equal to 25. The ratio of the magnetic permeability of the second magnetic layers 12 in the main surface direction to the magnetic permeability of the second magnetic layers 12 in the thickness direction is, for example, smaller than or equal to 20.

Examples usable as the materials of the first magnetic particles included in the first magnetic layer 11 include sendust (Fe—Si—Al) (5≤μ≤40, where μ denotes magnetic permeability), Fe—Si—B (5≤μ≤40), Fe—Si—Cr (5≤μ≤35), silicon steel (Fe—Si) (5≤μ≤30), and iron (Fe) (5≤μ≤25).

The magnetic permeability described above allows for the effects of the shapes of the first magnetic particles.

For example, the materials of the first magnetic particles may have magnetic permeability as follows: sendust (4000≤μ≤12000), Fe—Si—B (500≤μ≤4000), Fe—Si—Cr (300≤μ≤4000), and Fe (100≤μ≤5000).

Preferably, the first magnetic particles may be spherical particles. When the first magnetic particles spherical, the first magnetic particles have high flowability, and the compounding ratio at which the first magnetic particles occupy in the first magnetic layer 11 can be increased. When the first magnetic particles are spherical, the first magnetic layer 11 has isotropic magnetic permeability.

Examples usable as spherical particles include a particle with a flattening ratio measured in accordance with the definition of the flattening ratio, described later, of smaller than or equal to ⅓ (≈0.33).

Preferably, the first magnetic particles in the first magnetic layer 11 have flowability of higher than or equal to 50%. The flowability of the first magnetic particles can be calculated as a ratio of the area occupied by the first magnetic particles in the first magnetic layer 11 in a cross-sectional photo illustrated in FIG. 6. In this calculation, the area occupied by the inductor wires 20 is excluded from the area of the first magnetic layer 11.

Examples of the first resin contained in the first magnetic layer 11 include resin such as epoxy, phenol, and polyimide.

Examples of the materials usable as second magnetic particles included in the second magnetic layers 12 include sendust (Fe—Si—Al) (40≤μ≤200), Fe—Si—B (40≤μ≤100), Fe—Si—Cr (35≤μ≤80), and silicon steel (Fe—Si) (35≤μ≤60).

The magnetic permeability described above allows for the effects of the shapes of the second magnetic particles.

Examples of the materials of the second magnetic particles may have magnetic permeability as follows: sendust (4000≤μ≤12000), Fe—Si—B (500≤μ≤4000), and Fe—Si—Cr (300≤μ≤4000).

Preferably, the second magnetic particles have a higher average flattening ratio than the first magnetic particles.

FIG. 9 is a schematic cross-sectional view of a particle flattening ratio.

In a cross-sectional shape of particles, the direction in which the particles have a smallest dimension is defined as a Z direction, and one of two directions orthogonal to the Z direction in which the particles have a greater dimension is defined as an X direction. When the dimension (diameter) in the X direction is defined as a major axis a, and the dimension (diameter) in the Z direction is defined as a minor axis b, the flattening ratio f is expressed as f=1−(b/a). When the particles are spherical (circular cross section), the flattening ratio is 0, and when the particles have a completely flat shape, the flattening ratio is 1.

The first magnetic particles are preferably spherical particles, and the flattening ratio is thus preferably closer to 0. In contrast, the second magnetic particles have a plate-like cross-sectional shape, and the flattening ratio is thus preferably high, or preferably closer to 1. Thus, the flattening ratio of the second magnetic particles is preferably higher than the flattening ratio of the first magnetic particles.

The flattening ratios of the first magnetic particles and the second magnetic particles can be defined by measuring the dimensions of the particles in the cross-sectional photo illustrated in FIG. 6. The flattening ratio may be defined as a mean value of the measured flattening ratios of at least ten particles included in the cross-sectional photo.

Preferably, the second magnetic particles have a flat shape with a dimension in the main surface direction of the second magnetic layers 12 greater than the dimension in the thickness direction of the second magnetic layers 12. This means that the second magnetic particles having a high flattening ratio are oriented in the main surface direction of the second magnetic layers 12. Thus, the magnetic permeability of the second magnetic layers 12 in the main surface direction is higher than the magnetic permeability of the second magnetic layers 12 in the thickness direction.

Of the dimensions of the second magnetic particles, the dimension in the main surface direction of the second magnetic layers 12 (corresponding to the major axis a illustrated in FIG. 9) is preferably greater than or equal to 50 μm, and smaller than or equal to 1000 μm. The dimension in the thickness direction of the second magnetic layers 12 (corresponding to the minor axis b illustrated in FIG. 9) is preferably greater than or equal to 0.5 μm, and smaller than or equal to 50 μm.

Preferably, the flattening ratio of the second magnetic particles is greater than or equal to 0.9. The flattening ratio of the second magnetic particles may be any ratio smaller than 1. Preferably, the flattening ratio of the first magnetic particles is smaller than or equal to ⅓ (≈0.33). The flattening ratio of the first magnetic particles may be any ratio including zero, greater than or equal to 0.

Examples of the second resin included in the second magnetic layers 12 include epoxy, phenol, or polyimide. The type of the second resin may be the same as or different from the type of the first resin.

When the second magnetic layers 12 are disposed on both main surfaces of the first magnetic layer 11, the second magnetic particles and the second resin included in the second magnetic layer 12 disposed on one of the main surfaces of the first magnetic layer 11 may be different from the second magnetic particles and the second resin included in the second magnetic layer 12 disposed on the other main surface of the first magnetic layer 11, but preferably, they are the same.

Preferably, the thickness of the first magnetic layer 11 is greater than the thickness of the inductor wires 20 including the first wire 21 and the second wire 22. For example, the thickness of the first magnetic layer 11 is preferably greater than or equal to 105 μm, and smaller than or equal to 200 μm. The ratio of the thickness of the first magnetic layer 11 to the thickness of the magnetic body 10 is preferably greater than or equal to 10%, and smaller than or equal to 42%.

Preferably, the thickness of each second magnetic layer 12 is greater than the thickness of the first magnetic layer 11. For example, the thickness of each second magnetic layer 12 is preferably greater than or equal to 72 μm, and smaller than or equal to 450 μm.

Preferably, the inductor wires 20 including the first wire 21 and the second wire 22 have a thickness of greater than or equal to 100 μm to be appropriate to flowing a large current. Preferably, the thickness is smaller than or equal to 300 μm from the view point of thickness reduction of the package substrate 200.

Preferably, the width of the inductor wires 20 including the first wire 21 and the second wire 22 are greater than or equal to 50 μm. By increasing the width of the inductor wires 20, the inductor wires 20 have higher inductance, and are thus appropriate to flowing a large current. Preferably, the width of the inductor wires 20 is smaller than or equal to 1000 μm.

Preferably, the inductor wires 20 have an aspect ratio, or a ratio of the wire width to the wire thickness, of greater than or equal to 0.2. When the aspect ratio is greater than or equal to 0.2, the wire has a large thickness, and thus can flow a large current. Preferably, the aspect ratio is smaller than or equal to 4.

More specifically, preferably, the ratio of the thickness of the first wire 21 to the width of the first wire 21 is greater than or equal to 0.2, and the ratio of the thickness of the second wire 22 to the width of the second wire 22 is greater than or equal to 0.2. Preferably, the ratio of the thickness of the first wire 21 to the width of the first wire 21 is smaller than or equal to 4, and the ratio of the thickness of the second wire 22 to the width of the second wire 22 is smaller than or equal to 4.

When the plane along the main surface of the first magnetic layer 11 is viewed from above, preferably, as illustrated in FIG. 1, each of the first wire 21 and the second wire 22 included in the inductor wires 20 is a single wire formed by coupling multiple straight lines through which a current flows in different directions and having a straight or curved coupler that couples the multiple straight lines to each other. Preferably, the direction in which the current flows through a first straight line differs from the direction in which the current flows through a straight line adjacent to the first straight line.

The inductor wires 20 with this shape can obtain inductance unobtainable by a straight wire with high area efficiency. To cause the inductor wires 20 to function as an inductor, preferably, each inductor wire 20 is not a wire pattern that connects a first end and a second end with a straight line.

In the example illustrated in FIG. 1, the current flows through adjacent straight lines in exactly opposite directions. However, the current may flow in any directions that are different from each other, instead of opposite directions.

When the current flows through adjacent straight lines of a wire in different directions, the wire is different from a wound wire such as a wire having a helical shape, a spiral shape, or a whirling shape. In other words, the inductor wires 20 in the above example have an unwound shape. The inductor wires 20 may have a meander wire shape.

FIG. 10 is a schematic cross-sectional view of another example of a laminate structure of an inductor layer.

As in the inductor layer 250 illustrated in FIG. 5, an inductor layer 250B illustrated in FIG. 10 includes a magnetic body 10, and inductor wires 20 functioning as an inductor.

The magnetic body 10 includes a first magnetic layer 11 and a second magnetic layer 12. In the example illustrated in FIG. 10, the second magnetic layer 12 is disposed simply on one of the main surfaces of the first magnetic layer 11. In FIG. 10, the second magnetic layer 12 is disposed simply on the lower main surface of the first magnetic layer 11 without being disposed on the upper main surface of the first magnetic layer 11. Instead, the second magnetic layer 12 may be disposed simply on the upper main surface of the first magnetic layer 11 without being disposed on the lower main surface of the first magnetic layer 11.

Although the above description uses the expression of the upper surface and the lower surface of the first magnetic layer 11 in the drawings, the preferable position of the second magnetic layer 12 disposed simply on one of the main surfaces of the first magnetic layer 11 is determined with the relationship with components other than the inductor layer 250B. For example, preferably, the second magnetic layer 12 is disposed between the first magnetic layer 11 and the mount surface of the package substrate 200. In addition, when the package substrate 200 includes the capacitor layer 210, the second magnetic layer 12 is preferably disposed between the first magnetic layer 11 and the capacitor layer 210.

Hereafter, the relationship between the structure of an inductor layer and the characteristics of a coupled inductor is described.

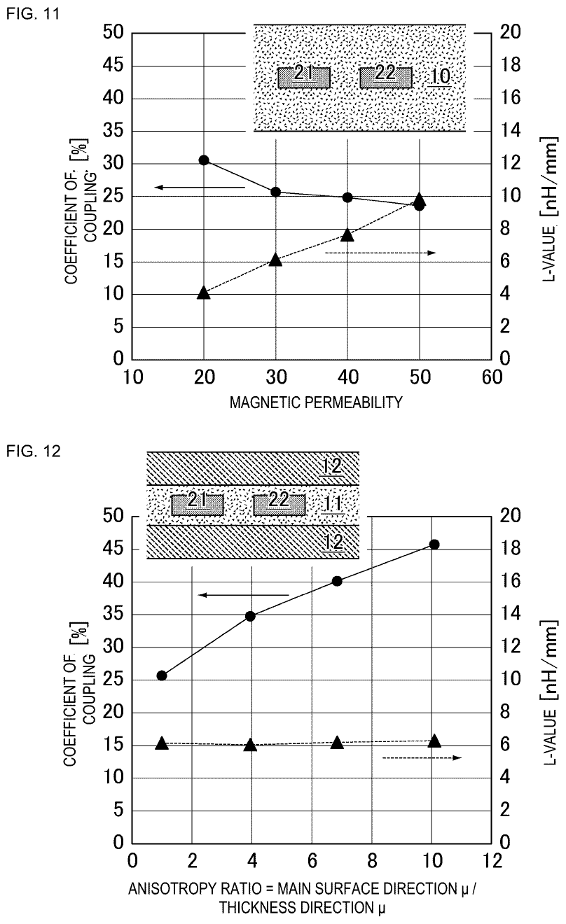

First, magnetic permeability dependence in a single-layer structure illustrated in FIG. 8 is studied. FIG. 11 is a graph of magnetic permeability dependence of a single-layer structure including a magnetic body entirely formed from the same isotropic material.

As is clear from FIG. 11, with an increase of magnetic permeability of the magnetic body 10, the coefficient of coupling does not increase, or rather decreases. In a structure including the magnetic body 10 with a relatively great thickness, an increase of magnetic permeability of the magnetic body 10 generally confines a magnetic flux in the magnetic body 10, and the coefficient of coupling increases with the inductance. In a structure where the magnetic body 10 is thin and the first wire 21 and the second wire 22 coupled to each other are arranged on the same plane, neither the coefficient of coupling nor the inductance increases. As illustrated in FIG. 11, to increase the coefficient of coupling, the magnetic permeability of the magnetic body 10 is required to be reduced, but instead, the inductance (indicated with an L-value in FIG. 11) decreases notably. When attention is focused simply on the coefficient of coupling, an air core is desirable, but that is not naturally the case.

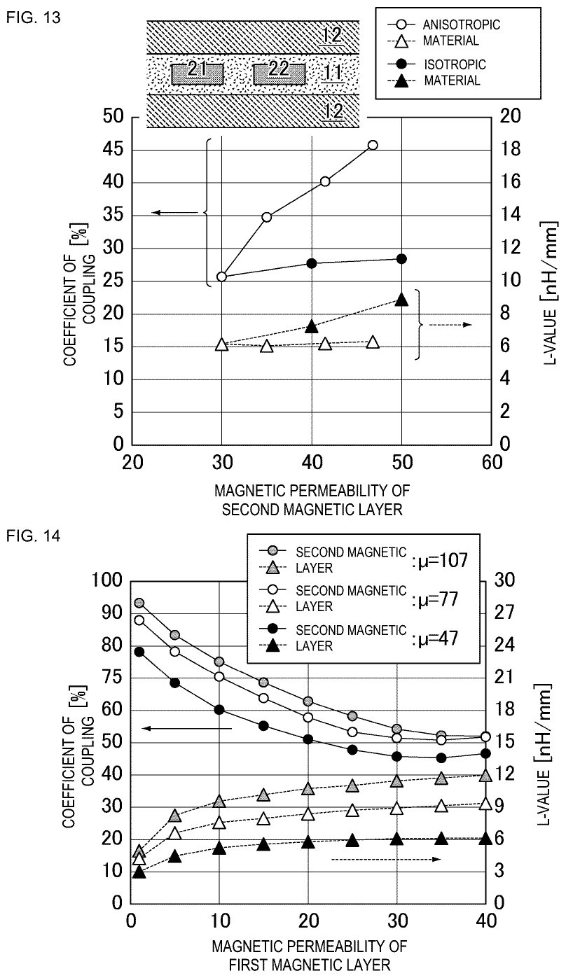

Subsequently, magnetic permeability dependence of the second magnetic layer in the laminate structure illustrated in FIG. 5 and FIG. 7 is studied. FIG. 12 is a graph of inductance dependence and a coefficient of coupling with respect to an anisotropy ratio of a second magnetic layer. FIG. 13 is a graph obtained by converting the graph illustrated in FIG. 12 into magnetic permeability dependence of the second magnetic layer in a main surface direction.

In FIG. 13, to change the anisotropy ratio or the ratio of the magnetic permeability of the second magnetic layer 12 in the main surface direction to the magnetic permeability of the second magnetic layer 12 in the thickness direction, the ratio is adjusted so that the entire second magnetic layer 12 has uniform magnetic permeability. The magnetic permeability in the main surface direction is changed (increases) as illustrated in FIG. 13 for this reason, but in contrast, the magnetic permeability in the thickness direction decreases. For example, when the anisotropy ratio is 10, the magnetic permeability μ in the main surface direction is approximately 47 (46.8), the magnetic permeability μ in the thickness direction is 4.7. This is the reason why the inductance scarcely changes with a change of the anisotropy ratio.

In comparison, FIG. 13 also illustrates the magnetic permeability dependence of a laminate structure similar to that in FIG. 5, but in a case where the second magnetic layer 12 is formed from an isotropic material. As illustrated in FIG. 13, in the laminate structure formed from an isotropic material, when the magnetic permeability of the second magnetic layer 12 in the main surface direction is increased, the coefficient of coupling and the inductance increase. Such a tendency is approximate to general magnetic permeability dependence, and the coefficient of coupling and the inductance change in a linked manner. In contrast, in the laminate structure formed from an anisotropic material, when the magnetic permeability of the second magnetic layer 12 in the main surface direction is increased, only the coefficient of coupling can be increased without increasing the inductance. More specifically, the anisotropy of the second magnetic layer 12 can increase only the coefficient of coupling without affecting the inductance. However, the use of an anisotropic material does not always prevent an increase of the inductance. Naturally, when magnetic permeability of the entire second magnetic layer 12 increases, the inductance increases, and the coefficient of coupling further increases.

As described above, when the second magnetic layer 12 having anisotropic magnetic permeability is laminated on the first magnetic layer 11 in which the first wire 21 and the second wire 22 magnetically coupled to each other are disposed, even a low-profile structure can effectively increase a coefficient of coupling.

The effect of coupling can reduce switching noise (SW noise) in a voltage regulator, and thus can improve the quality of components. In addition, reduction of the SW noise can lower the inductance. Thus, the length of the inductor wires 20 can be reduced, the direct current resistance can be reduced, and thus a loss can be reduced (in other words, the efficiency can be improved).

FIG. 14 is a graph of magnetic permeability dependence of a first magnetic layer in a laminate structure illustrated in FIG. 5.

In FIG. 14, while the anisotropy ratio and the magnetic permeability of the second magnetic layer 12 formed from an anisotropic material are fixed, the magnetic permeability of the first magnetic layer 11 formed from an isotropic material in the main surface direction is changed. The anisotropy ratio of the second magnetic layer 12 is fixed to 10, and the magnetic permeability μ in the main surface direction is changed between three levels of 47, 77, and 107.

As is clear from FIG. 14, the coefficient of coupling and the inductance have a trade-off relationship, and the relationship is changed by the magnetic permeability of the second magnetic layer 12. The inductance and the coefficient of coupling relate to an effect of reducing the SW noise in the voltage regulator, and when the inductance and the coefficient of coupling increase, the SW noise reduction effect also increases. However, the inductance and the coefficient of coupling do not increase together. Thus, how to set the magnetic permeability is difficult to determine.

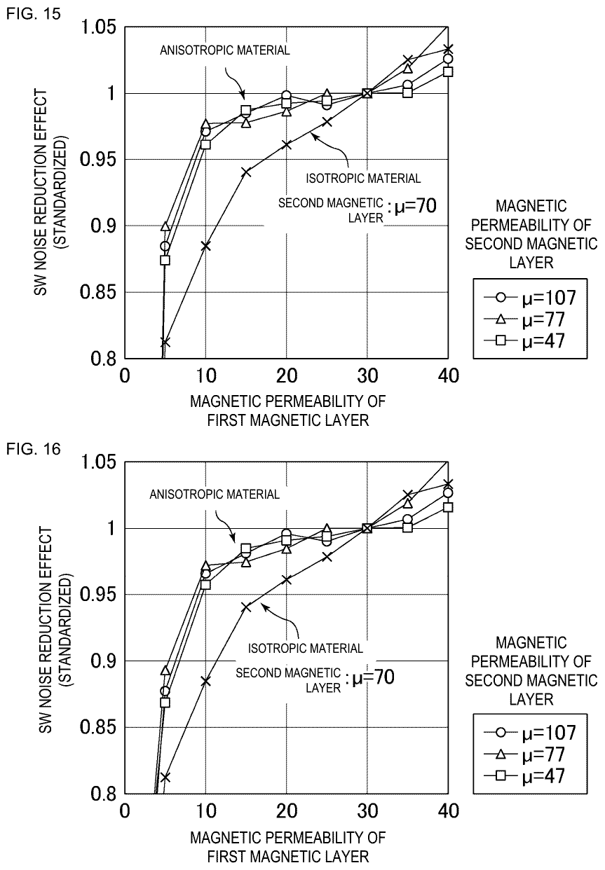

Thus, to check the SW noise reduction effect, the effects of the inductance and the coefficient of coupling are quantified using a circuit simulation. These values are standardized with values of standard conditions (magnetic permeability μ of magnetic body B=30), to deliver magnetic permeability dependence. FIG. 15 is a graph of magnetic permeability dependence of an SW noise reduction effect when the anisotropy ratio of the second magnetic layer is 10. FIG. 15 also illustrates results of a laminate structure (isotropic material illustrated in FIG. 13) including the above described second magnetic layer formed from an isotropic material.

As is clear from the results in FIG. 15, basically, the SW noise reduction effect increases with respect to the magnetic permeability of the first magnetic layer 11 in the main surface direction, and the ripple reduction effect increases when the magnetic permeability of the first magnetic layer 11 in the main surface direction increases. Particularly, when the magnetic permeability of the first magnetic layer 11 in the main surface direction is smaller than or equal to 5, the SW noise reduction effect decreases notably. This is an important tendency showing that the decreasing rate of the inductance is greater than the increasing rate of the coefficient of coupling, and that simply having a high coefficient of coupling is not necessarily advantageous. A non-magnetic body where the magnetic permeability of the first magnetic layer 11 in the main surface direction is 1 has a very low SW noise reduction effect, and is thus inappropriate to use.

When the second magnetic layer 12 is formed from an anisotropic material, the SW noise reduction effect improves within a range where the magnetic permeability of the first magnetic layer 11 in the main surface direction is greater than or equal to 10, and smaller than or equal to 25. In a range where the magnetic permeability of the first magnetic layer 11 in the main surface direction is greater than or equal to 10, the decrease in the SW noise reduction effect falls within 5%. More specifically, regardless of when the magnetic permeability of the first magnetic layer 11 in the main surface direction decreases, the ripple reduction effect scarcely decreases. This tendency results from the effect of the second magnetic layer 12 having anisotropic magnetic permeability.

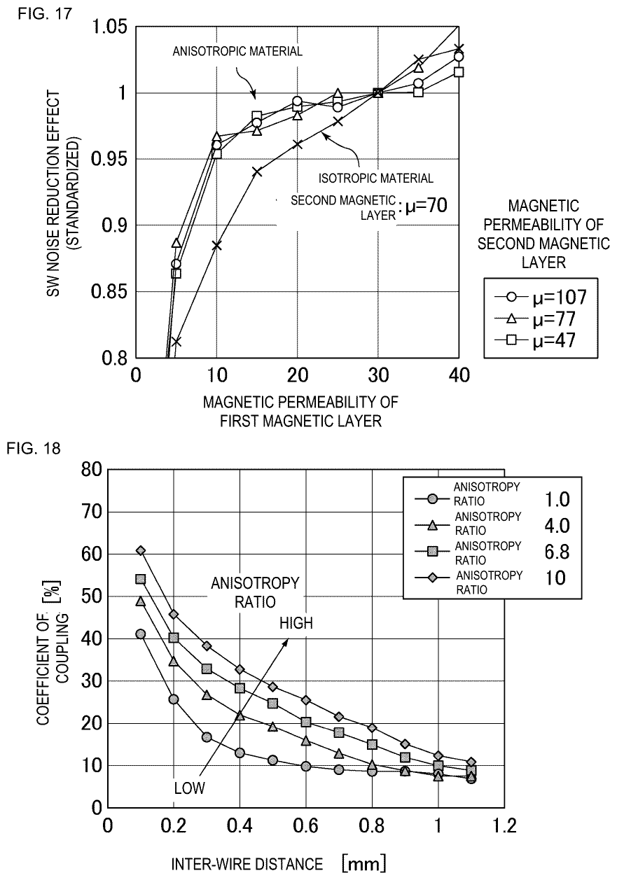

FIG. 16 is a graph of magnetic permeability dependence of an SW noise reduction effect when the anisotropy ratio of the second magnetic layer is 7. FIG. 17 is a graph of magnetic permeability dependence of an SW noise reduction effect when the anisotropy ratio of the second magnetic layer is 4.

The graphs in FIG. 16 and FIG. 17 illustrate the same tendency as the graph in FIG. 15. Thus, it is revealed that, when the second magnetic layer 12 has an anisotropy ratio of greater than or equal to 4, the decrease in the SW noise reduction effect within the range where the magnetic permeability of the first magnetic layer 11 in the main surface direction is greater than or equal to 10 falls within 5%.

As described above, when the second magnetic layer 12 has an anisotropy ratio of greater than or equal to 4, and the magnetic permeability of the first magnetic layer 11 in the main surface direction is greater than or equal to 10 and smaller than or equal to 25, the decrease in the SW noise reduction effect can be reduced. Compared to an increase of the magnetic permeability of the magnetic body 10, the magnetic permeability can be relatively easily decreased. The magnetic permeability can be reduced by, for example, decreasing the particle diameter of magnetic particles or using magnetic particles with smaller magnetic permeability. As described above, a decrease in the magnetic permeability without decreasing the SW noise reduction effect has the following effects:
Superimposition performance is improved.
High-frequency performance is improved.
Insulating characteristics and pressure resistance are improved.
Workability and flowability are improved with improved fluidity.

FIG. 18 is a graph of dependence with respect to an inter-wire distance in the laminate structure illustrated in FIG. 5.

As is clear from FIG. 18, the coefficient of coupling is changed notably with respect to the inter-wire distance (the coefficient of coupling increases notably with a decrease in the inter-wire distance), the inductance changes scarcely (the inductance decreases slightly when the inter-wire distance decreases), and, when the anisotropy ratio is high, the coefficient of coupling increases even in a structure with a great inter-wire distance.

The capacitor layer 210 constituting the package substrate 200 is now described in detail.

In the package substrate 200 illustrated in FIG. 2, the capacitor layer 210 includes, for example, a capacitor portion 230, an electroconductive portion 240 electrically connected to the through-hole conductor 262 at the output terminal OUT, an electroconductive portion (not illustrated) electrically connected to a through-hole conductor (not illustrated) at the ground terminal GND (refer to FIG. 4), and an insulator 225 disposed around these components.

The second magnetic layer 12 of the inductor layer 250 is located between the first magnetic layer 11 of the inductor layer 250 and the capacitor layer 210.

In the present embodiment, the capacitor portion 230 includes an anode plate 231 formed from metal. For example, the anode plate 231 includes a core portion 232 formed from a valve metal. Preferably, the anode plate 231 includes porous portions 234 disposed on at least one of main surfaces of the core portion 232. A dielectric layer (not illustrated) is disposed on the surface of at least one porous portion 234, and a cathode layer 236 is disposed on the surface of the dielectric layer. Thus, in the present embodiment, the capacitor portion 230 forms an electrolytic capacitor.

When the capacitor portion 230 forms an electrolytic capacitor, the anode plate 231 is formed from a valve metal having a valve function. Examples of a valve metal include a single metal such as aluminum, tantalum, niobium, titanium, and zirconium, and an alloy including at least one of these metals. Among these, aluminum or an aluminum alloy is preferable.

The anode plate 231 preferably has a flat shape, and more preferably, a foil shape. The anode plate 231 includes the porous portion 234 on at least one of the main surfaces of the core portion 232, or may have the porous portion 234 on each of two main surfaces of the core portion 232. The porous portion 234 is preferably a porous layer disposed on the surface of the core portion 232, or more preferably, an etching layer.

The dielectric layer disposed on the surface of the porous portion 234 is porous by reflecting the surface state of the porous portion 234, and thus has a surface state with fine protrusions and recesses. Preferably, the dielectric layer is formed from an oxide film of the valve metal. For example, when aluminum foil is used as the anode plate 231, the surface of the aluminum foil undergoes anodic oxidation treatment (also referred to as chemical conversion treatment) in a solution containing, for example, an ammonium adipate, and thus, a dielectric layer formed from an oxide film can be formed.

The cathode layer 236 disposed on the surface of the dielectric layer includes, for example, a solid electrolyte layer disposed on the surface of the dielectric layer. Preferably, the cathode layer 236 further includes an electroconductive layer disposed on the surface of the solid electrolyte layer.

Examples of the material forming the solid electrolyte layer include an electroconductive polymer such as a polypyrrole group, a polythiophene group, and a polyaniline group. Among these, a polythiophene group is preferable, and poly (3,4-ethylenedioxythiophene) called PEDOT is particularly preferable. The electroconductive polymer may contain a dopant such as polystyrene sulfonate (PSS). Preferably, the solid electrolyte layer includes an inner layer with which pores (recesses) in the dielectric layer are filled, and an outer layer that covers the dielectric layer.

The electroconductive layer includes at least one of an electroconductive resin layer and a metal layer. The electroconductive layer may simply include an electroconductive resin layer or a metal layer. Preferably, the electroconductive layer covers the entire surface of the solid electrolyte layer.

Examples of the electroconductive resin layer includes an electroconductive adhesive layer containing at least one electroconductive filler selected from the group consisting of a silver filler, a copper filler, a nickel filler, and a carbon filler.

Examples of the metal layer include a metal plating film and a metal foil. Preferably, the metal layer is formed from at least one metal selected from the group consisting of nickel, copper, silver, and an alloy containing any of these metals as a main component. Here, the term “main component” refers to a component of an element having the greatest weight ratio.

The electroconductive layer includes, for example, a carbon layer disposed on the surface of the solid electrolyte layer, and a copper layer disposed on the surface of the carbon layer.

The carbon layer is disposed to electrically and mechanically connect the solid electrolyte layer and the copper layer to each other. The carbon layer can be disposed in a predetermined area by applying carbon paste onto the solid electrolyte layer by a method such as sponge transfer, screen printing, dispenser application, or inkjet printing.

The copper layer can be disposed in a predetermined area by applying copper paste onto the carbon layer by a method such as sponge transfer, screen printing, spraying, dispenser application, or inkjet printing.

The electroconductive portion 240 electrically connected to the through-hole conductor 262 at the output terminal OUT is formed mainly from a metal with low resistance such as silver (Ag), gold (Au), or copper (Cu). To improve interlayer adhesion, an electroconductive adhesive obtained by mixing the electroconductive filler and a resin may be disposed as an electroconductive portion. The electroconductive portion electrically connected to the through-hole conductor at the ground terminal GND may have the same structure as the structure of the electroconductive portion 240.

The insulator 225 is formed from an insulating material, for example, a resin such as epoxy, phenol, or polyimide, or a mixed material of a resin such as epoxy, phenol, or polyimide, and an inorganic filler such as silica or alumina.

As illustrated in FIG. 2, the cathode layer 236 serving as a cathode of the capacitor portion 230 is electrically connected to the through-hole conductor 262 at the output terminal OUT through, for example, via conductors 242 and the electroconductive portion 240.

Although not illustrated in FIG. 2, the core portion 232 serving as an anode of the capacitor portion 230 is electrically connected to a through-hole conductor at the ground terminal GND through, for example, a via conductor and an electroconductive portion. Alternatively, the core portion 232 serving as an anode of the capacitor portion 230 may be directly electrically connected to the through-hole conductor at the ground terminal GND.

A ceramic capacitor formed from a barium titanate, or a thin-film capacitor formed from a silicon nitride (SiN), a silicon dioxide (SiO₂), or a hydrogen fluoride (HF) may be used as the capacitor portion 230. However, to form the capacitor portion 230 with a smaller thickness and a relatively large area, and in view of the mechanical characteristics of the package substrate 200 including stiffness and flexibility, the capacitor portion 230 is preferably a capacitor formed from metal such as aluminum as a base material, or more preferably, an electrolytic capacitor formed from metal such as aluminum as a base material.

The resin layers 226, 227, and 228 are used as joining materials to join the layers to one another, and also used as insulator layers to insulate the exposed surfaces of the capacitor layer 210 and the inductor layer 250. The capacitor layer 210 and the inductor layer 250 are joined with the resin layer 227. The resin layer 226 is disposed on the upper surface of the capacitor layer 210, and the resin layer 228 is disposed on the bottom surface of the inductor layer 250. The resin layers 226, 227, and 228 are formed from an insulating material, for example, a resin such as epoxy, polyimide, or phenol, or a mixed material containing a resin such as epoxy, polyimide, or phenol, and an inorganic filler such as silica or alumina. To ensure close contact with the through-hole conductors, a material mainly containing an epoxy resin is preferably used as the resin layers.

The upper-surface terminal layer 205 including lands on which devices including the voltage regulator 100 are mounted and wires to connect these is disposed on the surface of the resin layer 226. The devices mounted on the package substrate 200 are electrically connected to the lands or the terminals of the upper-surface terminal layer 205 through solder bumps 120.

The upper-surface terminal layer 205 is formed from a metal with low resistance such as Cu, Au, or Ag. Instead of the upper-surface terminal layer 205 formed only on the surface of the resin layer 226, for example, multiple upper-surface terminal layers 205 may be disposed in the resin layer 226. Preferably, for ease of mounting of devices, the surfaces of the lands or the terminals disposed on the mount surface of the upper-surface terminal layer 205 are treated by, for example, nickel/gold (Ni/Au) plating, nickel/lead/gold (Ni/Pb/Au) plating, or organic solderability preservative. To prevent flowing of solder during surface mounting of devices, a solder resist layer may be disposed at an outermost layer portion of the upper-surface terminal layer 205.

Preferably, the package substrate 200 includes through-hole conductors 261 and 262 that extend through the first magnetic layer 11 and the second magnetic layer 12 in the magnetic body 10 in the thickness direction. The through-hole conductor 261 is connected to a first end (IN) of each inductor wire 20, and the through-hole conductor 262 is connected to a second end (OUT) of the inductor wire 20.

Preferably, the package substrate 200 includes through-hole conductors (not illustrated in FIG. 2) that extend through the first magnetic layer 11 and the second magnetic layer 12 in the magnetic body 10 in the thickness direction, and that are used as ground lines (GND).

By using these through-hole conductors, the wire impedance can be lowered, and the layout of the circuit plane can be minimized. Thus, the size of the semiconductor composite device 1 can be reduced.

The package substrate 200 described above includes one inductor layer 250 and one capacitor layer 210. However, to obtain a desired inductance value and a desired capacitance value, the package substrate 200 may include multiple inductor layers 250 and multiple capacitor layers 210. In addition, the inductor layer 250 and the capacitor layer 210 may be laminated in the opposite order from the mount surface. More specifically, the inductor layer 250 may be located closer to the side on which the voltage regulator 100 and the load 300 are mounted. In addition, in accordance of purpose of use, the package substrate 200 may have a multilayer structure including the inductor layer 250, the capacitor layer 210, and the inductor layer 250 laminated in this order, or a multilayer structure including the capacitor layer 210, the inductor layer 250, and the capacitor layer 210 laminated in this order. Alternatively, the package substrate 200 may have a single-layer structure including the inductor layer 250.

### [Method for Manufacturing Package Substrate]

To manufacture the package substrate 200 illustrated in FIG. 2, the capacitor layer 210 and the inductor layer 250 are individually manufactured. Thereafter, the capacitor layer 210 and the inductor layer 250 are joined and integrated using the resin layers 226, 227, and 228. Thereafter, through-hole conductors are formed in the capacitor layer 210 and the inductor layer 250 integrated together. Thereafter, an electrode pattern and a wire pattern to serve as the upper-surface terminal layer 205 are formed on the mount surface to complete the package substrate 200. As needed, an electrode pattern and a wire pattern to serve as the bottom-surface terminal layer 270 may be formed on the surface opposite to the mount surface.

When a device such as the voltage regulator 100 is mounted on the completed package substrate 200, the semiconductor composite device 1 is complete.

The inductor layer 250 constituting the package substrate 200 can be manufactured with the following processes.

(1) Both surfaces of Cu foil are patterned with, for example, a photoresist, and an opening portion of the photoresist is etched to form the inductor wires 20 with a predetermined pattern.

(2) With vacuum lamination or vacuum pressing, magnetic sheets serving as a composite material including the first magnetic particles and the first resin are disposed on the inductor wires 20 while filling a space in the pattern of the inductor wires 20. In addition, flattening and thermosetting of a resin material are performed using a hot press. Thus, the first magnetic layer 11 containing the inductor wires 20 is formed. The magnetic sheets may be disposed on the inductor wires 20 from both surfaces, or one by one on each surface.

(3) With vacuum lamination or vacuum pressing, magnetic sheets serving as a composite material including the second magnetic particles and the second resin are disposed on the upper surface and the lower surface of the first magnetic layer 11. Thus, the second magnetic layers 12 are formed. The second magnetic layer 12 may be formed simply on one of the main surfaces of the first magnetic layer 11.

(4) A resin layer (such as Ajinomoto Build-Up Film or ABF) is disposed on the surface of each second magnetic layer 12. The capacitor layer 210 and the inductor layer 250 are then joined and integrated with the resin layer interposed therebetween as described above.

(5) Via holes or through-holes are formed at portions of the inductor wires 20 corresponding to take-out electrodes using a drill or laser.

(6) The inner sides of via holes or through-holes are plated to form via conductors or through-hole conductors to be connected to the inductor wires 20. These conductors may be either conformal of filling conductors, but preferably filling conductors to flow a large current.

(7) When the electrode pattern and the wire pattern are formed on the mount surface, the package substrate 200 is completed.

A package substrate and a semiconductor composite device according to other embodiments are described below.

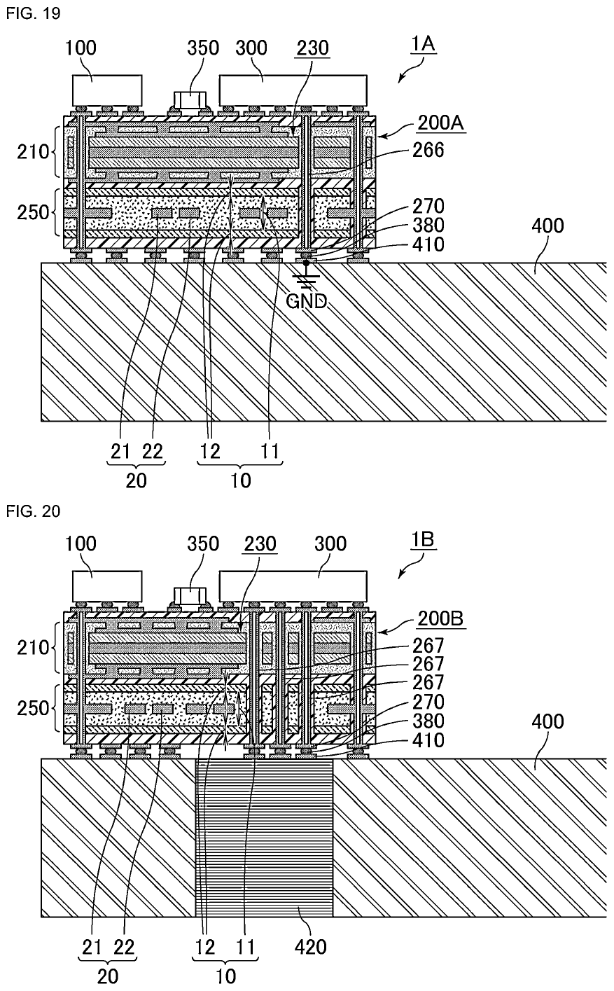

FIG. 19 is a schematic cross-sectional view of an example of a semiconductor composite device mounted on a motherboard.

A package substrate 200A included in a semiconductor composite device 1A illustrated in FIG. 19 includes a through-hole conductor 266 connected to a terminal of a signal ground line of the load 300 when the load 300 is mounted on the package substrate 200A. The through-hole conductor 266 extends through to the bottom-surface terminal layer 270 without being electrically connected to the capacitor portion 230 included in the capacitor layer 210 and the inductor wires 20 included in the inductor layer 250. The through-hole conductor 266 is then electrically connected to a terminal 410 connected to the ground line of a motherboard 400 through a solder bump 380.

With reference to FIG. 19, the through-hole conductor of the ground line of the load 300 is described, but the through-hole conductor of a ground line of another electronic device may have the same structure. The package substrate 200A may simply include the inductor layer 250 without including the capacitor layer 210. In the inductor layer 250, the second magnetic layer 12 may be disposed on at least one of the main surfaces of the first magnetic layer 11.

FIG. 20 is a schematic cross-sectional view of another example of a semiconductor composite device mounted on a motherboard.

A package substrate 200B included in a semiconductor composite device 1B illustrated in FIG. 20 includes through-hole conductors 267 connected to the load 300 when the load 300 is mounted on the package substrate 200B. The through-hole conductors 267 extend through to the bottom-surface terminal layer 270 without being electrically connected to the capacitor portion 230 included in the capacitor layer 210 and the inductor wires 20 included in the inductor layer 250. The through-hole conductors 267 are then electrically connected to the terminal 410 connected to a heat sink 420 of the motherboard 400 through the solder bump 380.

The heat sink 420 is a member with high thermal conductivity such as a copper block. Heat generated by driving the load 300 can be transferred to the heat sink 420 through the through-hole conductors 267. More specifically, the through-hole conductors 267 are used as heat dissipation paths. This structure can improve allowable power.

FIG. 20 illustrates three through-hole conductors 267, but the number of through-hole conductors 267 is not limitative. The package substrate 200B may simply include the inductor layer 250 without including the capacitor layer 210. In the inductor layer 250, the second magnetic layer 12 may be disposed on at least one of the main surfaces of the first magnetic layer 11.

### REFERENCE SIGNS LIST

1, 1A, 1B semiconductor composite device
10 magnetic body
11 first magnetic layer
12 second magnetic layer
20 inductor wire
21 first wire
22 second wire
50 inductor layer
100 voltage regulator
120 solder bump
200, 200A, 200B package substrate
205 upper-surface terminal layer
210 capacitor layer
225 insulator
226, 227, 228 resin layer
230 capacitor portion
231 anode plate
232 core portion
234 porous portion
236 cathode layer
240 electroconductive portion
242 via conductor
250, 250A, 250B inductor layer
261, 262, 266, 267 through-hole conductor
270 bottom-surface terminal layer
300 load
350 electronic device
380 solder bump
400 motherboard
410 terminal
420 heat sink
CP1 capacitor
L1 inductor
D inter-wire distance

1. A package substrate comprising:
an inductor layer including
a magnetic body including
a first magnetic layer including first magnetic particles and a first resin, and
a second magnetic layer on at least one main surface of the first magnetic layer and including second magnetic particles and a second resin, and
inductor wires in the first magnetic layer, the inductor wires including
a first wire and a second wire adjacent to each other on a same plane along the at least one main surface of the first magnetic layer such that the first wire and the second wire are magnetically coupled,
wherein the second magnetic layer is extends across the first wire and the second wire so as to overlap the first wire and the second wire in a thickness direction,
wherein the second magnetic layer has anisotropic magnetic permeability in which a magnetic permeability in a main surface direction thereof differs from a magnetic permeability in the thickness direction thereof,
wherein the magnetic permeability of the second magnetic layer in the main surface direction thereof is higher than the magnetic permeability of the second magnetic layer in the thickness direction thereof, and
wherein the magnetic permeability of the second magnetic layer in the main surface direction thereof is higher than a magnetic permeability of the first magnetic layer in a main surface direction thereof.

2. The package substrate according to claim 1, wherein the second magnetic particles have a flat shape with a dimension in the main surface direction of the second magnetic layer greater than a dimension in the thickness direction of the second magnetic layer.

3. The package substrate according to claim 1, wherein a ratio of the magnetic permeability of the second magnetic layer in the main surface direction thereof to the magnetic permeability of the second magnetic layer in the thickness direction thereof is greater than or equal to 4.

4. The package substrate according to claim 3, wherein the magnetic permeability of the first magnetic layer in the main surface direction thereof is greater than or equal to 10 and smaller than or equal to 25.

5. The package substrate according to claim 1,
wherein a ratio of a thickness of the first wire to a width of the first wire is greater than or equal to 0.2, and
wherein a ratio of a thickness of the second wire to a width of the second wire is greater than or equal to 0.2.

6. The package substrate according to claim 1, wherein the second magnetic layer is on each of two main surfaces of the first magnetic layer.

7. The package substrate according to claim 1, wherein the first magnetic layer is between the second magnetic layer and the first wire.

8. The package substrate according to claim 1, wherein a surface of the first wire is at an interface between the first magnetic layer and the second magnetic layer.

9. The package substrate according to claim 1, wherein the first magnetic layer is between the second magnetic layer and each of the first wire and the second wire.

10. The package substrate according to claim 1, wherein a surface of each of the first wire and the second wire is at an interface between the first magnetic layer and the second magnetic layer.

11. An inductor component comprising:
a magnetic body including
a first magnetic layer including first magnetic particles and a first resin and
a second magnetic layer on at least one main surface of the first magnetic layer and including second magnetic particles and a second resin, and
inductor wires in the first magnetic layer, the inductor wires including a first wire and a second wire adjacent to each other on a same plane along the at least one main surface of the first magnetic layer such that the first wire and the second wire are magnetically coupled; and
an outer electrode on an outer surface of the magnetic body and electrically connected to the inductor wires,
wherein the second magnetic layer is extends across the first wire and the second wire so as to overlap the first wire and the second wire in a thickness direction,
wherein the second magnetic layer has anisotropic magnetic permeability in which a magnetic permeability in a main surface direction thereof differs from a magnetic permeability in the thickness direction thereof,
wherein the magnetic permeability of the second magnetic layer in the main surface direction thereof is higher than the magnetic permeability of the second magnetic layer in the thickness direction thereof, and
wherein the magnetic permeability of the second magnetic layer in the main surface direction thereof is higher than a magnetic permeability of the first magnetic layer in a main surface direction thereof.

12. The inductor component according to claim 11, wherein the second magnetic particles have a flat shape with a dimension in the main surface direction of the second magnetic layer greater than a dimension in the thickness direction of the second magnetic layer.

13. The inductor component according to claim 11, wherein a ratio of the magnetic permeability of the second magnetic layer in the main surface direction thereof to the magnetic permeability of the second magnetic layer in the thickness direction thereof is greater than or equal to 4.

14. The inductor component according to claim 13, wherein the magnetic permeability of the first magnetic layer in the main surface direction thereof is greater than or equal to 10 and smaller than or equal to 25.

15. The inductor component according to claim 11,
wherein a ratio of a thickness of the first wire to a width of the first wire is greater than or equal to 0.2, and
wherein a ratio of a thickness of the second wire to a width of the second wire is greater than or equal to 0.2.

16. The inductor component according to claim 11, wherein the second magnetic layer is on each of two main surfaces of the first magnetic layer.

17. The inductor component according to claim 11, wherein the first magnetic layer is between the second magnetic layer and the first wire.

18. The inductor component according to claim 11, wherein a surface of the first wire is at an interface between the first magnetic layer and the second magnetic layer.

19. The inductor component according to claim 11, wherein the first magnetic layer is between the second magnetic layer and each of the first wire and the second wire.

20. The inductor component according to claim 11, wherein a surface of each of the first wire and the second wire is at an interface between the first magnetic layer and the second magnetic layer.
